(19) United States
(12) Patent Application Publication
(10) Pub. No.: US 2024/0072227 A1
(43) Pub. Date: Feb. 29, 2024

(54) SEMICONDUCTOR DEVICE

(71) Applicant: ROHM CO., LTD., Ukyo-ku (JP)

(72) Inventor: Kazuya MASUYAMA, Ukyo-ku (JP)

(21) Appl. No.: 18/358,815

(22) Filed: Jul. 25, 2023

(30) Foreign Application Priority Data
Aug. 26, 2022 (JP) 2022-134927

(51) Int. Cl. H01L 33/62; H01L 23/00

(52) U.S. Cl. CPC H01L 33/62; H01L 24/32; H01L 24/48; H01L 24/92; H01L 33/60; H01L 2224/32225; H01L 2224/48091; H01L 2224/48225; H01L 2224/73265; H01L 2224/92247; H01L 2924/12041; H01L 2933/0066

(57) ABSTRACT

A semiconductor device includes: a substrate including a main surface; a semiconductor element; a connection material; a first bonding wire; and a second bonding wire, wherein the substrate includes a conductor layer on the main surface, the main surface includes a first and second regions, the conductor layer includes a first pattern in the first region and a second pattern in the second region, one and the other ends of the second bonding wire are respectively connected to the semiconductor element and the second pattern, a recess is formed in the first region and includes a first end and a second end which is opposite the first end and is closer to the second region than the first end in the first direction, and the first end is between the semiconductor element and the other end of the first bonding wire in the first direction.

### CROSS-REFERENCE TO RELATED APPLICATION

This application is based upon and claims the benefit of priority from Japanese Patent Application No. 2022-134927, filed on Aug. 26, 2022, the entire contents of which are incorporated herein by reference.

### TECHNICAL FIELD

The present disclosure relates to a semiconductor device.

### BACKGROUND

In the related art, a semiconductor light-emitting device is disclosed. The semiconductor light-emitting device disclosed in the related art includes a substrate, a semiconductor light-emitting element, and a bonding wire. The substrate includes a base material and a conductive portion. The conductive portion is disposed on a main surface of the base material. The semiconductor light-emitting element is disposed on the conductive portion. The bonding wire includes one end connected to the semiconductor light-emitting element and the other end connected to the conductive portion.

### BRIEF DESCRIPTION OF DRAWINGS

The accompanying drawings, which are incorporated in and constitute a part of the specification, illustrate embodiments of the present disclosure.

FIG. 1 is a plan view of a semiconductor device.

FIG. 2 is a cross-sectional view taken along line II-II in FIG. 1.

FIG. 3 is a front view of the semiconductor device.

FIG. 4 is a cross-sectional view of a semiconductor device according to a modification.

FIG. 5 is a manufacturing process diagram of the semiconductor device.

FIG. 6 is a cross-sectional view for explaining a first etching step.

FIG. 7 is a cross-sectional view for explaining a second etching step.

FIG. 8 is a cross-sectional view for explaining a peripheral wall formation step.

FIG. 9 is a cross-sectional view for explaining a die bonding step.

FIG. 10 is a cross-sectional view for explaining a wire bonding step.

FIG. 11 is a cross-sectional view for explaining a resin sealing step.

FIG. 12 is a cross-sectional view of a semiconductor device.

FIG. 13 is a plan view of a semiconductor device.

FIG. 14 is a cross-sectional view taken along line XIV-XIV in FIG. 13.

FIG. 15 is a cross-sectional view of a semiconductor device according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An embodiment of the present disclosure will be described with reference to the drawings. Throughout the drawings, the same or corresponding parts are denoted by the same reference numerals, and duplicate explanation thereof will not be repeated.

### First Embodiment

A semiconductor device according to an embodiment of the present disclosure will be described. A semiconductor device according to a first embodiment of the present disclosure is referred to as a semiconductor device 100.

### <Configuration of Semiconductor Device 100>

The configuration of the semiconductor device 100 will be described below.

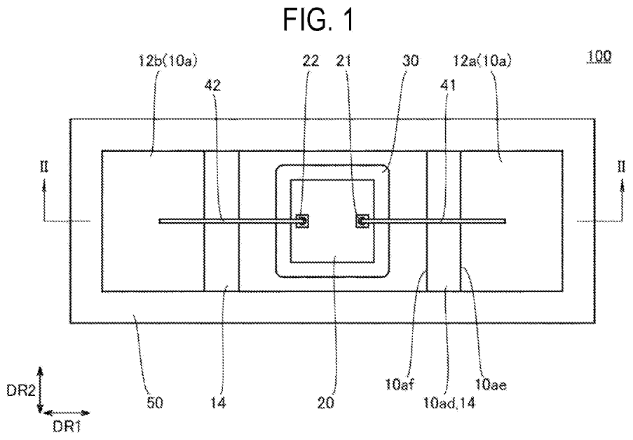

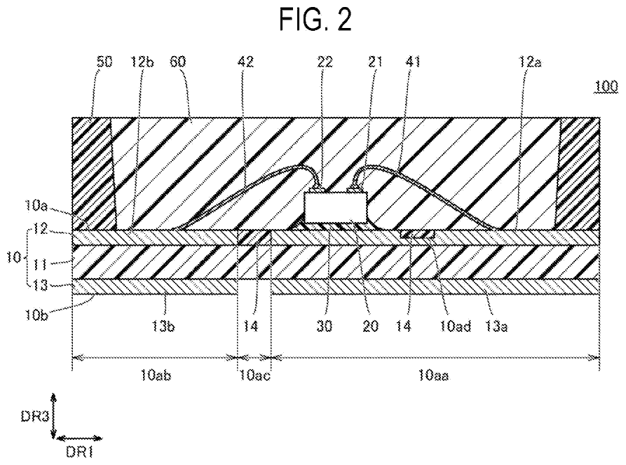

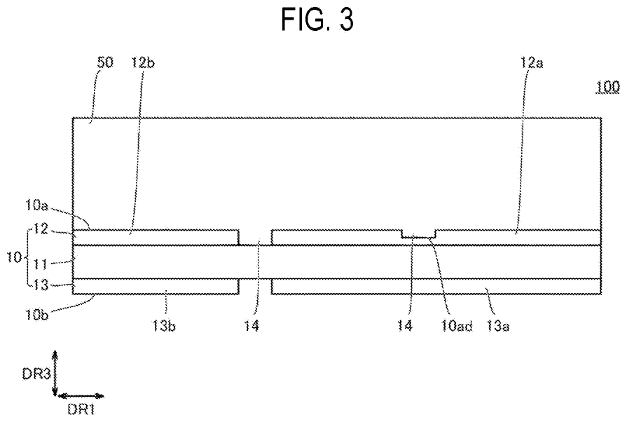

FIG. 1 is a plan view of the semiconductor device 100. It should be noted that a sealing material 60 is not shown in FIG. 1. FIG. 2 is a cross-sectional view taken along line II-II in FIG. 1. FIG. 3 is a front view of the semiconductor device 100. As shown in FIGS. 1 to 3, the semiconductor device 100 includes a substrate 10, a semiconductor element 20, a connection material 30, bonding wires 41 and 42, a peripheral wall 50, and a sealing material 60.

The substrate 10 includes a main surface 10a and a main surface 10b. The main surface 10a and the main surface 10b are end surfaces of the substrate 10 in a thickness direction thereof. The main surface 10b is a surface opposite the main surface 10a. The substrate 10 has a rectangular shape in a plan view. The plan view refers to a case where the semiconductor device 100 is viewed from a main surface 10a side along a normal direction of the main surface 10a. A longitudinal direction of the substrate 10 in a plan view is referred to as, for example, a first direction DR1. A second direction DR2 is a direction perpendicular to the first direction DR1 in a plan view.

The main surface 10a is divided into a first region 10aa, a second region 10ab, and a third region 10ac in a plan view. The third region 10ac is between the first region 10aa and the second region 10ab in the first direction DR1. That is, the first region 10aa and the second region 10ab are separated from each other in the first direction DR1. In a plan view, the first region 10aa, the second region 10ab, and the third region 10ac have a rectangular shape. From another point of view, a boundary between the first region 10aa and the third region 10ac and a boundary between the second region 10ab and the third region 10ac are along the second direction DR2.

The substrate 10 includes a base material 11, a conductor layer 12, and a conductor layer 13. The conductor layer 12 is disposed on one main surface of the base material 11. The conductor layer 13 is disposed on the other main surface of the base material 11. That is, the substrate 10 includes the conductor layer 12 on the main surface 10a and the conductor layer 13 on the main surface 10b. The base material 11 is made of an electrically insulating material. The base material 11 is made of, for example, glass epoxy. The conductor layers 12 and 13 are made of an electrically conductive material, more specifically, a metal material. The conductor layers 12 and 13 are made of, for example, copper (Cu).

The conductor layer 12 includes a first pattern 12a and a second pattern 12b. The first pattern 12a is in the first region 10aa. In the example shown in FIGS. 1 to 3, the first pattern 12a is over the entire surface of the first region 10aa except for a portion where a recess 10ad is formed.

The second pattern 12b is in the second region 10ab. In the example shown in FIGS. 1 to 3, the second pattern 12b is over the entire surface of the second region 10ab. The conductor layer 12 is removed in the third region 10ac. That is, the first pattern 12a and the second pattern 12b are electrically isolated from each other. Surfaces of the first pattern 12a and the second pattern 12b may be subjected to plating treatment. That is, the first pattern 12a and the second pattern 12b may include a plated film on their surfaces. The plated film is, for example, a silver (Ag)-plated film.

The conductor layer 13 includes a first pattern 13a and a second pattern 13b. The first pattern 13a and the second pattern 13b are respectively on a portion of the main surface 10b on the opposite side to the first region 10aa and a portion of the main surface 10b on the opposite side to the second region 10ab. Although not shown, the base material 11 is formed with a first through-hole and a second through-hole penetrating the base material 11 along a thickness direction thereof. The first pattern 12a and the first pattern 13a are electrically connected to each other by a conductor embedded in the first through-hole, and the second pattern 12b and the second pattern 13b are electrically connected to each other by a conductor embedded in the second through-hole.

The recess 10ad is formed in the first region 10aa. The recess 10ad extends along the second direction DR2 in a plan view. Both ends of the recess 10ad in the second direction DR2 preferably reach an outer peripheral edge of the main surface 10a. The recess 10ad includes a first end 10ae and a second end 10af in the first direction DR1. The second end 10af is an end on the opposite side to the first end 10ae and is closer to the second region 10ab (the third region 10ac) than the first end 10ae.

A resin material 14 is embedded in the recess 10ad. A surface of the resin material 14 embedded in the recess 10ad is preferably flush with the main surface 10a around the surface of the resin material 14. The resin material 14 is also embedded between the first pattern 12a and the second pattern 12b. A surface of the resin material 14 embedded between the first pattern 12a and the second pattern 12b is preferably flush with the main surface 10a around the surface of the resin material 14.

The semiconductor element 20 is, for example, a light-emitting element. The light-emitting element is, for example, an LED (Light-emitting Diode). However, the semiconductor element 20 is not limited thereto. The connection material 30 is, for example, a die bond paste. The die bond paste contains a resin material and has, for example, an electrical insulation. The semiconductor element 20 is disposed on the first region 10aa with the connection material 30 interposed therebetween. More specifically, the semiconductor element 20 is disposed on the first pattern 12a with the connection material 30 interposed therebetween. The semiconductor element 20 is fixed to the substrate 10 by the connection material 30. A bonding pad 21 and a bonding pad 22 are formed on an upper surface of the semiconductor element 20.

One end and the other end of the bonding wire 41 are connected to the bonding pad 21 and the first pattern 12a, respectively. The recess 10ad is between the other end of the bonding wire 41 and the semiconductor element 20 in the first direction DR1. More specifically, the recess 10ad is disposed such that first end 10ae is between the other end of the bonding wire 41 and the semiconductor element 20. One end and the other end of the bonding wire 42 are connected to the bonding pad 22 and the second pattern 12b, respectively. The bonding wires 41 and 42 are made of, for example, gold (Au), copper, or the like.

The peripheral wall 50 is disposed on the outer peripheral edge of the main surface 10a. The peripheral wall 50 surrounds the semiconductor element 20 in a plan view. The peripheral wall 50 rises from the main surface 10a along a third direction DR3. The third direction DR3 is a direction orthogonal to the first direction DR1 and the second direction DR2. The peripheral wall 50 preferably functions as a reflector when the semiconductor element 20 is a light-emitting element. That is, it is preferable that the peripheral wall 50 is made of a material that reflects light from the semiconductor element 20. A specific example of the material that reflects light from the semiconductor element 20 is a resin material mixed with titanium oxide (TiO₂) particles. A constituent material of the peripheral wall 50 is preferably the same as that of the resin material 14.

An inner wall surface of the peripheral wall 50 may be inclined such that a distance from an outer wall surface of the peripheral wall 50 increases as the inner wall surface of the peripheral wall 50 approaches the lower end of the peripheral wall 50. The light from the semiconductor element 20 is reflected by the inner wall surface of the peripheral wall 50 and is then emitted from above the semiconductor device 100.

The sealing material 60 fills a space defined by the substrate 10 (the main surface 10a) and the peripheral wall 50. Thus, the first pattern 12a, the second pattern 12b, the semiconductor element 20, the connection material 30, the bonding wire 41, and the bonding wire 42 are sealed. The sealing material 60 is made of an electrically insulating material. When the semiconductor element 20 is a light-emitting element, the sealing material 60 is preferably made of transparent resin.

### <Modification>

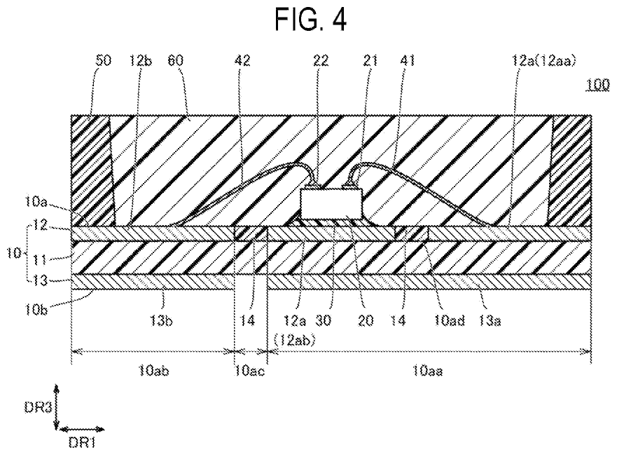

FIG. 4 is a cross-sectional view of a semiconductor device 100 according to a modification. As shown in FIG. 4, the recess 10ad may penetrate the first pattern 12a. That is, the base material 11 may be exposed from the recess 10ad. In this case, the first pattern 12a may be separated into a first portion 12aa and a second portion 12ab by the recess 10ad. The semiconductor element 20 is disposed on the second portion 12ab with the connection material 30 interposed therebetween, and the other end of the bonding wire 41 is connected to the first portion 12aa.

### <Manufacturing Method of Semiconductor Device 100>

A method of manufacturing the semiconductor device 100 will be described below.

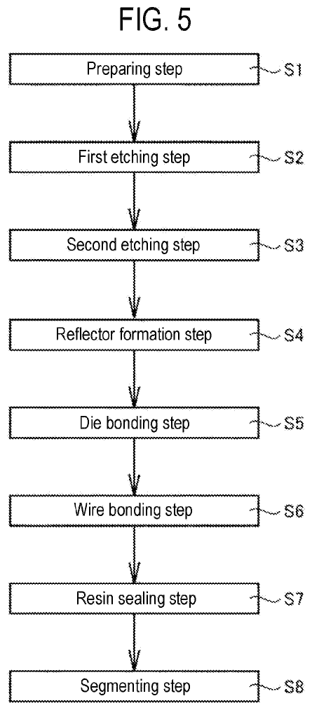

FIG. 5 is a manufacturing process diagram of the semiconductor device 100. As shown in FIG. 5, the method of manufacturing the semiconductor device 100 includes a preparing step S1, a first etching step S2, a second etching step S3, a peripheral wall formation step S4, a die bonding step S5, a wire bonding step S6, a resin sealing step S7, and a segmenting step S8.

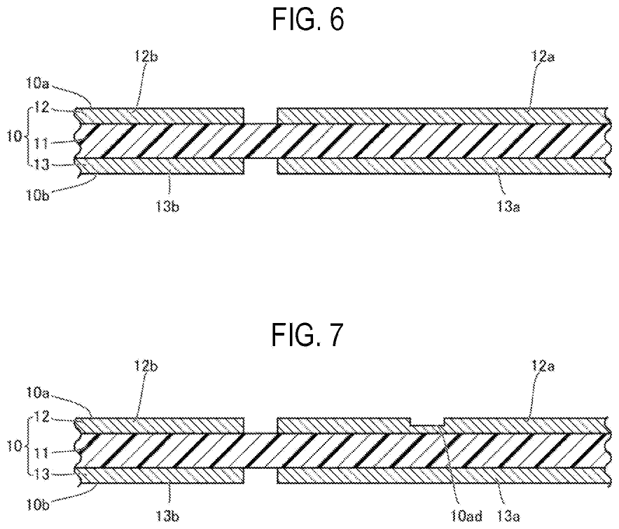

In the preparing step S1, the substrate 10 is prepared. In the substrate 10 prepared in the preparing step S1, the conductor layer 12 and the conductor layer 13 are not patterned. The first etching step S2 is performed after the preparing step S1. FIG. 6 is a cross-sectional view for explaining the first etching step S2. As shown in FIG. 6, the conductor layer 12 and the conductor layer 13 are etched in the first etching step S2. As a result, the conductor layer 12 is patterned to form the first pattern 12a and the second pattern 12b, and the conductor layer 13 is patterned to form the first pattern 13a and the second pattern 13b.

The second etching step S3 is performed after the first etching step S2. FIG. 7 is a cross-sectional view for explaining the second etching step S3. As shown in FIG. 7, in the second etching step S3, the recess 10ad is formed by etching the first pattern 12a. In a case where the recess 10ad penetrates the first pattern 12a, the recess 10ad may be formed in the first etching step S2, and the second etching step S3 may be omitted.

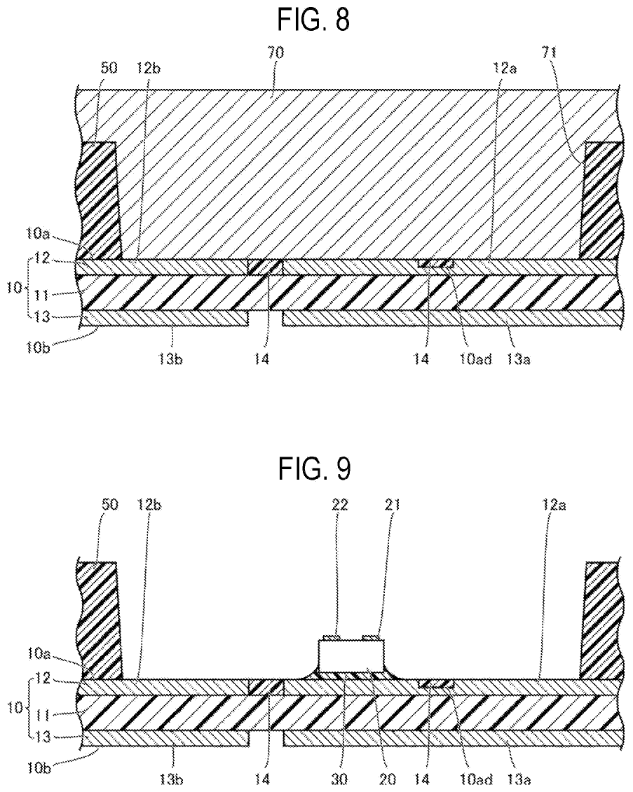

The peripheral wall formation step S4 is performed after the second etching step S3. FIG. 8 is a cross-sectional view for explaining the peripheral wall formation step S4. As shown in FIG. 8, the peripheral wall 50 is formed in the peripheral wall formation step S4. The peripheral wall 50 is formed by transfer molding by using a mold 70. The mold 70 is disposed to be in contact with the main surface 10a. A flow path 71 is formed in the mold 70. The peripheral wall 50 is formed by injecting the constituent material of the peripheral wall 50 into the flow path 71. Further, the constituent material of the peripheral wall 50 is also injected between the mold 70 and the main surface 10a, more specifically, inside the recess 10ad and between the first pattern 12a and the second pattern 12b. Therefore, when the peripheral wall 50 is formed, the resin material 14 of the same constituent material as the peripheral wall 50 is embedded in the recess 10ad and between the first pattern 12a and the second pattern 12b.

The die bonding step S5 is performed after the peripheral wall formation step S4. FIG. 9 is a cross-sectional view for explaining the die bonding step S5. As shown in FIG. 9, in the die bonding step S5, the semiconductor element 20 is connected to the first pattern 12a by using the connection material 30. In the die bonding step S5, first, an unhardened connection material 30 is applied onto the first pattern 12a. Second, the semiconductor element 20 is mounted on the unhardened connection material 30. Third, the semiconductor element 20 is connected to the first pattern 12a by the connection material 30 by heating and hardening the connection material 30.

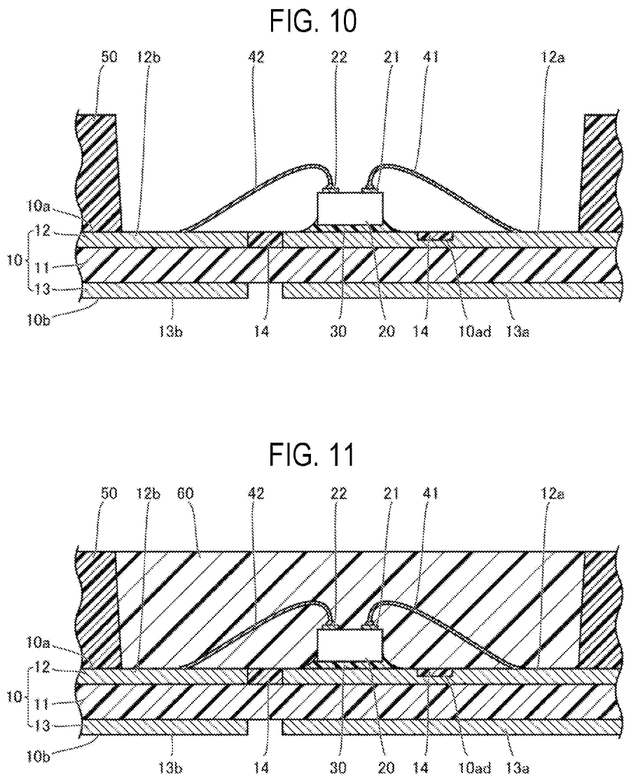

The wire bonding step S6 is performed after the die bonding step S5. FIG. 10 is a cross-sectional view for explaining the wire bonding step S6. As shown in FIG. 10, in the wire bonding step S6, wire bonding is performed to connect the bonding pad 21 to the first pattern 12a with the bonding wire 41 and connect the bonding pad 22 to the second pattern 12b with the bonding wire 42.

The resin sealing step S7 is performed after the wire bonding step S6. FIG. 11 is a cross-sectional view for explaining the resin sealing step S7. As shown in FIG. 11, in the resin sealing step S7, an unhardened sealing material 60 is potted in the space defined by the substrate 10 and the peripheral wall 50 by using a dispenser and is hardened by heating. The segmenting step S8 is performed after the resin sealing step S7. In the segmenting step S8, the substrate 10 and the peripheral wall 50 are cut to be segmented into a plurality of semiconductor devices 100. From the above, the semiconductor device 100 with the structure shown in FIGS. 1 to 3 is formed.

### <Effects of Semiconductor Device 100>

Effects of the semiconductor device 100 will be described below in comparison with a semiconductor device according to a comparative example. The semiconductor device according to the comparative example is referred to as a semiconductor device 200.

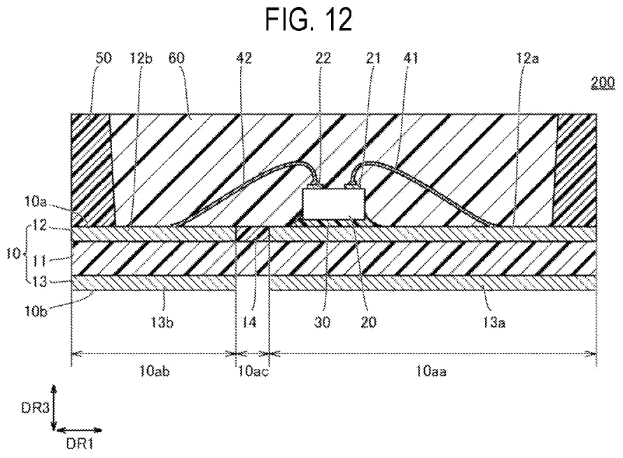

FIG. 12 is a cross-sectional view of the semiconductor device 200. As shown in FIG. 12, a configuration of the semiconductor device 200 is the same as the configuration of the semiconductor device 100 except that the recess 10ad is not formed in the first region 10aa (the first pattern 12a). In the semiconductor device 200, in the die bonding step S5, the connection material 30 bleeds (wets and spreads) on the first pattern 12a to a point to which the other end of the bonding wire 41 is connected, which may cause connection failure between the bonding wire 41 and the first pattern 12a.

On the other hand, in the semiconductor device 100, the first end 10ae is between the other end of the bonding wire 41 and the semiconductor element 20 in the first direction DR1. Wettability of the connection material 30 on the resin material 14 embedded in the recess 10ad is lower than that of the connection material 30 on the first pattern 12a made of the metal material. Therefore, the connection material 30 is less likely to spread beyond the resin material 14 embedded in the recess 10ad to the point to which the other end of the bonding wire 41 is connected, thereby preventing a connection failure between the bonding wire 41 and the first pattern 12a.

When the peripheral wall 50 is made of the same constituent material as the resin material 14, since the resin material 14 may be embedded in the recess 10ad at the same time when the peripheral wall 50 is formed in the peripheral wall formation step S4, it is possible to simplify the manufacturing process of the semiconductor device 100. Further, in the semiconductor device 100, the resin material 14 may be embedded in the recess 10ad at the same time when the peripheral wall 50 is formed without changing the mold 70 when manufacturing the semiconductor device 200. When the recess 10ad penetrates the first pattern 12a, the recess 10ad may be formed in the first etching step S2, and the second etching step S3 may be omitted.

When both ends of the recess 10ad in the second direction DR2 reach the outer peripheral edge of the main surface 10a, a contact area between the peripheral wall 50 and the main surface 10a (the first pattern 12a) increases. Therefore, in this case, it is possible to improve adhesiveness between the peripheral wall 50 and the main surface 10a.

### Second Embodiment

A semiconductor device according to a second embodiment of the present disclosure will be described. The semiconductor device according to the second embodiment is referred to as a semiconductor device 100A. Here, differences from the semiconductor device 100A will be mainly described, and duplicate explanation thereof will not be repeated.

### <Configuration of Semiconductor Device 100A>

A configuration of the semiconductor device 100A will be described below.

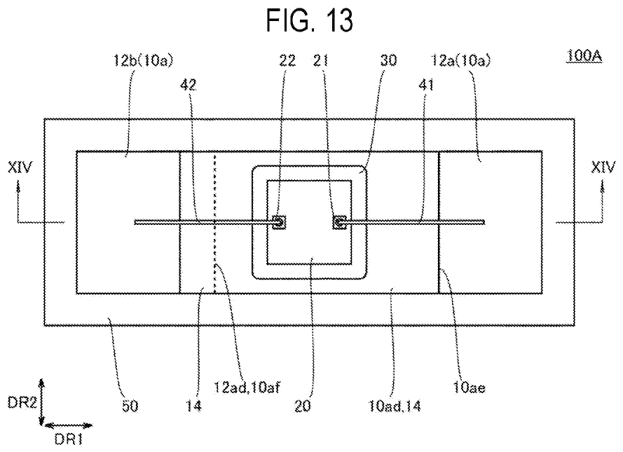

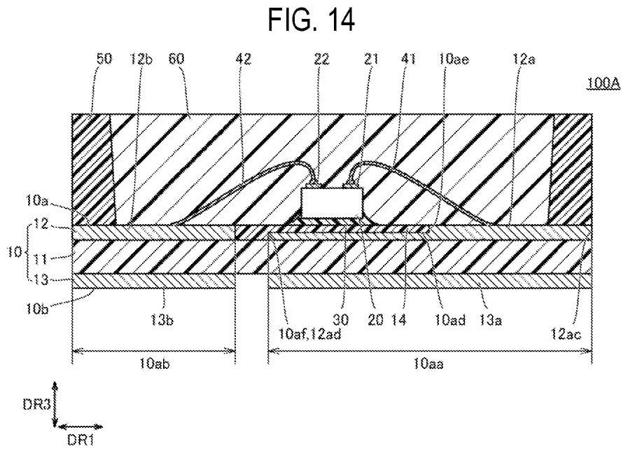

FIG. 13 is a plan view of the semiconductor device 100A. The sealing material 60 is not shown in FIG. 13. FIG. 14 is a cross-sectional view taken along line XIV-XIV in FIG. 13. As shown in FIGS. 13 and 14, the semiconductor device 100A includes the substrate 10, the semiconductor element 20, the connection material 30, the bonding wires 41 and 42, the peripheral wall 50, and the sealing material 60. In the semiconductor device 100A, the recess 10ad is formed in the first region 10aa. In the semiconductor device 100A, the first end 10ae is between the other end of the bonding wire 41 and the semiconductor element 20 in the first direction DR1. Regarding these points, the configuration of the semiconductor device 100A is the same as the configuration of the semiconductor device 100.

Both ends of the first pattern 12a in the first direction DR1 are referred to as a third end 12ac and a fourth end 12ad, respectively. The fourth end 12ad is closer to the second pattern 12b (the third region 10ac) than the semiconductor element 20 in the first direction DR1. In the semiconductor device 100A, the second end 10af reaches the fourth end 12ad. That is, in the semiconductor device 100A, the semiconductor element 20 is disposed on the resin material 14 embedded in the recess 10ad with the connection material 30 interposed therebetween. Regarding these points, the configuration of the semiconductor device 100A is different from the configuration of the semiconductor device 100.

### <Effects of Semiconductor Device 100A>

The effects of the semiconductor device 100A will be described below.

Peeling may occur at an interface between the first pattern 12a and the sealing material 60. In the semiconductor device 100A, since the second end 10af reaches the fourth end 12ad, the interface between the sealing material 60 and the first pattern 12a is reduced. Therefore, according to the semiconductor device 100A, it is possible to suppress the occurrence of peeling at the interface between the first pattern 12a and the sealing material 60.

When a silver-plated film is formed on a surface of the first pattern 12a, the silver-plated film may be discolored (lose metallic luster) due to sulfurization or ionization, and the discoloration of the silver-plated film lowers reflectance. In the semiconductor device 100A, since the second end 10af reaches the fourth end 12ad, an area of the main surface 10a in which the reflectance is lowered due to the discoloration of the silver-plated film is reduced, it possible to improve utilization efficiency of light from the semiconductor element 20.

As compared to a case where the recess 10ad is formed to penetrate the first pattern 12a, as will be described later, when the recess 10ad does not penetrate the first pattern 12a, since a rigidity of the substrate 10 may be easily ensured by the first pattern 12a below the recess 10ad, bending of the substrate 10 when the mold 70 is pressed is suppressed.

### <Modification>

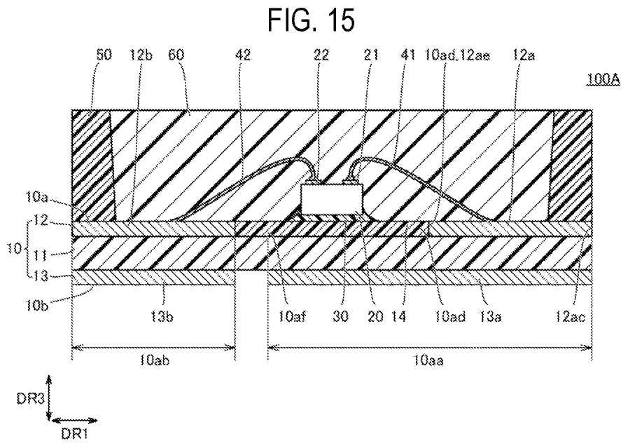

FIG. 15 is a cross-sectional view of a semiconductor device 100A according to a modification. As shown in FIG. 15, in the semiconductor device 100A, the recess 10ad may penetrate the first pattern 12a. In this case, the recess 10ad may be formed in the first etching step S2, and the second etching step S3 may be omitted.

### (Supplementary Notes)

Hereinafter, configurations of the semiconductor device according to the present disclosure will be additionally described as supplementary notes.

### <Supplementary Note 1>

A semiconductor device including:
a substrate including a main surface;
a semiconductor element;
a connection material;
a first bonding wire; and
a second bonding wire,
wherein the substrate includes a conductor layer on the main surface,
wherein the main surface includes a first region and a second region that are separated from each other in a first direction in a plan view,
wherein the conductor layer includes a first pattern in the first region and a second pattern in the second region,
wherein the semiconductor element is disposed on the first region with the connection material interposed therebetween,
wherein one end and the other end of the first bonding wire are connected to the semiconductor element and the first pattern, respectively,
wherein one end and the other end of the second bonding wire are connected to the semiconductor element and the second pattern, respectively,
wherein a recess is formed in the first region,
wherein the recess includes a first end and a second end which is opposite the first end and is closer to the second region than the first end in the first direction, and
wherein the first end is between the semiconductor element and the other end of the first bonding wire in the first direction.

### <Supplementary Note 2>

The semiconductor device of Supplementary Note 1, wherein the recess is formed in the first pattern, and
wherein the second end is between the first end and the semiconductor element in the first direction.

### <Supplementary Note 3>

The semiconductor device of Supplementary Note 1, wherein the recess is formed in the first pattern,
wherein the first pattern includes a third end and a fourth end which is opposite the third end and is closer to the second pattern than the semiconductor element in the first direction, and
wherein the second end reaches the fourth end.

### <Supplementary Note 4>

The semiconductor device of any one of Supplementary Notes 1 to 3, wherein a plated film is formed on a surface of the first pattern.

### <Supplementary Note 5>

The semiconductor device of Supplementary Note 4, wherein the plated film is a silver-plated film.

### <Supplementary Note 6>

The semiconductor device of any one of Supplementary Notes 1 to 5, wherein a resin material is embedded in the recess.

### <Supplementary Note 7>

The semiconductor device of any one of Supplementary Notes 1 to 6, further including a peripheral wall disposed on an outer peripheral edge of the main surface to surround the semiconductor element in a plan view,
wherein a constituent material of the peripheral wall is the same as the resin material.

### <Supplementary Note 8>

The semiconductor device of Supplementary Note 7, wherein the recess extends along a second direction perpendicular to the first direction in a plan view, and
wherein both ends of the recess in the second direction reach the outer peripheral edge of the main surface.

### <Supplementary Note 9>

The semiconductor device of Supplementary Note 7 or 8, further including: a sealing material with which a space defined by the substrate and the peripheral wall is filled.

### <Supplementary Note 10>

The semiconductor device of Supplementary Note 9, wherein the semiconductor element is a light-emitting element,
wherein a constituent material of the sealing material is a transparent resin, and
wherein the constituent material of the peripheral wall is a material that reflects light from the light-emitting element.

Although the embodiments of the present disclosure have been described as above, it is also possible to modify the above-described embodiments in various ways. In addition, the scope of the present disclosure is not limited to the above-described embodiments. The scope of the present disclosure is indicated by the claims and is intended to include all changes within the meaning and scope equivalent to the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a substrate including a main surface;
a semiconductor element;
a connection material;
a first bonding wire; and
a second bonding wire,
wherein the substrate includes a conductor layer on the main surface,
wherein the main surface includes a first region and a second region that are separated from each other in a first direction in a plan view,
wherein the conductor layer includes a first pattern in the first region and a second pattern in the second region,
wherein the semiconductor element is disposed on the first region with the connection material interposed therebetween,
wherein one end and the other end of the first bonding wire are connected to the semiconductor element and the first pattern, respectively,
wherein one end and the other end of the second bonding wire are connected to the semiconductor element and the second pattern, respectively,
wherein a recess is formed in the first region,
wherein the recess includes a first end and a second end which is opposite the first end and is closer to the second region than the first end in the first direction, and
wherein the first end is between the semiconductor element and the other end of the first bonding wire in the first direction.

2. The semiconductor device of claim 1, wherein the recess is formed in the first pattern, and
wherein the second end is between the first end and the semiconductor element in the first direction.

3. The semiconductor device of claim 1, wherein the recess is formed in the first pattern,
wherein the first pattern includes a third end and a fourth end which is opposite the third end and is closer to the second pattern than the semiconductor element in the first direction, and
wherein the second end reaches the fourth end.

4. The semiconductor device of claim 3, wherein a plated film is formed on a surface of the first pattern.

5. The semiconductor device of claim 4, wherein the plated film is a silver-plated film.

6. The semiconductor device of claim 1, wherein a resin material is embedded in the recess.

7. The semiconductor device of claim 6, further comprising a peripheral wall disposed on an outer peripheral edge of the main surface to surround the semiconductor element in a plan view,
wherein a constituent material of the peripheral wall is the same as the resin material.

8. The semiconductor device of claim 7, wherein the recess extends along a second direction perpendicular to the first direction in a plan view, and
wherein both ends of the recess in the second direction reach the outer peripheral edge of the main surface.

9. The semiconductor device of claim 8, further comprising a sealing material with which a space defined by the substrate and the peripheral wall is filled.

10. The semiconductor device of claim 9, wherein the semiconductor element is a light-emitting element,
wherein a constituent material of the sealing material is a transparent resin, and
wherein the constituent material of the peripheral wall is a material that reflects light from the light-emitting element.
